(19) United States
(12) Patent Application Publication
(10) Pub. No.: US 2006/0292459 A1
(43) Pub. Date: Dec. 28, 2006

(54) EUV reflection mask and method for producing it

(76) Inventors: Frank-Michael Kamm, Dresden (DE); Siegfried Schwarzl, Neubiberg (DE); Christian Holfeld, Dresden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/453,947

(22) Filed: Jun. 15, 2006

(30) Foreign Application Priority Data
Jun. 15, 2005 (DE) 10 2005 027 697.0

(51) Int. Cl. G03F 1/00; G21K 5/00

(52) U.S. Cl. 430/5; 378/35

(57) ABSTRACT

An EUV mask having elevated sections and trenches lying in between is disclosed. In one embodiment, the mask includes at least a substrate layer having a very low coefficient of thermal expansion, a multilayer, and a capping layer. The elevated sections of the EUV mask are arranged on a continuous conductive layer.

### CROSS-REFERENCE TO RELATED APPLICATIONS

This Utility Patent Application claims priority to German Patent Application No. DE 10 2005 027 697.0 filed on Jun. 15, 2005, which is incorporated herein by reference.

### FIELD OF THE INVENTION

The invention relates to a mask for EUV technology, and to a method for producing EUV masks.

### BACKGROUND

In the fabrication of microchips, thin layers of photoresist are used for the patterning of semiconductor substrates. The photoresists can be altered selectively in their chemical nature by exposure with the aid of a photomask or by direct irradiation, for example by means of an electron beam. The exposed or non-exposed regions can thus be removed selectively by means of a developer since, depending on the resist used, only the exposed or unexposed regions are soluble in the developer. After a development process in which the exposed or non-exposed regions of the photoresist are removed, a patterned photoresist is obtained which is used as a mask for example during the etching of the semiconductor substrate.

Actinic radiation is generally used during the irradiation of photoresist, the radiation usually being generated by a laser source. At the present time, the shortest wavelength of the radiation used lies within the range of 157-193 nm.

In order to overcome the limits given by the resolution capability of present-day conventional photolithography techniques, it is attempted to use radiations having ever shorter wavelengths for the exposure of the photoresists. A multiplicity of materials and apparatuses have been developed for radiations having a wavelength of more than 193 nm, and in part for radiations having a wavelength of 157 nm. However, the advances achieved in semiconductor technology require the resolution of even smaller structures, which can only be produced by using a radiation having an even shorter wavelength. Extreme UV (EUV) technology, which is now in the pilot phases, uses radiation of 13.4 nm, which requires completely new technological approaches.

The radiation of 13.4 nm is far below the wavelength of visible light and is close to the range of X-rays. Since EUV radiation has the property that it is absorbed by almost every material, it is no longer possible to use the conventional systems with transparent masks and refractive optics, such as lenses. The EUV radiation is therefore focused by highly reflective mirror optics, shaped and directed onto the wafer to be patterned.

The EUV masks therefore have a highly reflective surface and must have the property that they retain their form in the event of increasing heat. In order to achieve the two requirements for an EUV mask, a multilayer system is applied to a substrate having a particularly low thermal expansion. Typically, 80 to 120 layers made of molybdenum and silicon each having a thickness of 2 to 4 nm are alternately deposited. Part of the radiation is reflected at each interface of the molybdenum/silicon layers, so that ideally above 70% of the incident radiation can be reflected.

The exposure radiation does not impinge perpendicularly on the EUV mask, but rather at a small angle of incidence relative to the perpendicular, and is reflected from reflective regions of the reflection mask and then falls onto the light-sensitive layer of the wafer.

A conventional reflective mask for EUV lithography is explained below with reference to FIG. 1.

On a multilayer 2 lying on a substrate 1 and comprising molybdenum and silicon layers, radiation-absorbing regions 3 are formed from an absorber layer applied beforehand on the front side V. The absorbing regions 3 are situated in elevated fashion on the multilayer 2, and radiation-reflecting regions 4 of the multilayer 2 arise between the absorbing regions 3. The elevated radiation-absorbing regions 3 and the radiation-reflecting regions (trenches) 4 of the multilayer correspond to patterns that are to be exposed on the semiconductor wafer.

The exposure radiation, which is represented by arrows depicted, impinges on the reflection mask at a small angle a with respect to the perpendicular.

A method for producing a conventional EUV mask is explained in more detail with reference to FIG. 2.

A multilayer 2 comprising alternate molybdenum and silicon layers 2a, 2b is deposited on a substrate 1 made of e.g. ULE® glass or Zerodur® ceramic. The respective molybdenum and silicon layers are extremely thin and have a thickness of approximately 2.7-2.8 nm (molybdenum layer) and approximately 4.2-4.3 nm (silicon layer). The topmost layer of this multilayer comprises silicon and is referred to as “capping layer”. The capping layer has a thickness of approximately 11 nm. A buffer layer 5 made of e.g. SiO2 is then deposited on the multilayer, the buffer layer having a thickness of 50 nm, for example. The buffer layer 5 serves as a stop layer during the patterning of the EUV mask.

In a further method process, an absorber layer 3 is deposited, which may comprise e.g. aluminum-copper, chromium or tantalum nitride. The structure thus obtained is depicted in FIG. 2b. A resist is then deposited (not shown) onto this structure, exposed and developed in order to obtain the structure in accordance with FIG. 2c after removal of the uncovered absorber layer 3 and subsequent removal of the resist.

Since defects very often occur during the production of EUV masks, the resulting defects are then eliminated in a repair process, conventionally using FIB (Focus-Ion-Beam). The buffer layer 5 is then removed in order to obtain a finished mask (FIG. 2d).

The masks depicted in FIGS. 1 and 2 are also known as absorber EUV masks.

In addition to the traditional absorber masks that have been illustrated in FIGS. 1 and 2, a further mask type referred to as “etched multilayer mask” is proposed, in which the reflective multilayer itself is patterned, as a result of which the use of a buffer layer and absorber layer is obviated. This mask type affords some advantages with regard to process window size, positional displacement of the structures and horizontal-vertical bias, but is more difficult to realize in production. One reason for the increased difficulty of production resides, inter alia, in charging effects of the structures upon exposure with ionizing radiation or charged particles (e.g. electrons), since, in the patterned regions, large areas of nonconductive substrate lie open and insulated structures occur. These charging effects prevent correct inspection by means of electron microscopy, repair with charged particles, such as e.g. ions or electrons, and double or further structure generation by writing by means of charged particles. The problem has previously been able to be solved in part by means of a second exposure which protects the multilayer hard mask against hard mask stripping in relatively large unpatterned regions and thus produces a conductive surface in the protected regions. However, this method is complicated and can only be employed for relatively large unpatterned regions. This method cannot be employed within the finely patterned zones. It is likewise possible, during the structure generation on the mask, to use a conductive resist or a conductive additional layer with respect to the resist.

These problems also occur in the case of the absorber masks, but to a small extent.

For these and other reasons there is a need for the present invention.

### SUMMARY

The present invention provides an EUV mask having elevated sections and trenches lying in between. In one embodiment, the mask includes a substrate layer having a very low coefficient of thermal expansion, a multilayer made of e.g. molybdenum and silicon, and a capping layer (made of e.g. silicon). The elevated sections of the EUV mask are arranged on a continuous conductive layer. The present invention also provides a method of making a mask.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a conventional reflective mask for EUV lithography.

FIG. 2a illustrates the method for producing a conventional EUV mask.

FIG. 2b illustrates the structure thus obtained.

FIG. 2c illustrates a resist deposited (not shown) onto this structure, exposed and developed in order to obtain the structure after removal of the uncovered absorber layer and subsequent removal of the resist.

FIG. 2d illustrates the buffer layer removed in order to obtain a finished mask.

FIGS. 3a-3e illustrate the method for producing an EUV mask of the absorber type according to the invention.

FIGS. 4a-4f illustrate a production method for the EUV etched multilayer masks.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides an EUV mask which overcomes the disadvantages of the EUV masks in accordance with the prior art, and in particular an EUV mask which can be inspected more easily. Further, the present invention provides a method for producing EUV masks.

In one embodiment, the EUV mask according to the invention has a continuous conductive layer in which the elevated sections are arranged, the mask having the following layers:
a substrate having a very low coefficient of thermal expansion (such as e.g. ULE® or Zerodur®);
a conductive base layer made of, e.g., chromium, tantalum nitride, conductive carbon layers, aluminum copper, iron, cobalt or nickel;
if appropriate a smoothing layer made of e.g. silicon;
a multilayer constructed from a plurality of alternate molybdenum and silicon thin layers and a final capping layer (e.g. made of silicon);
if appropriate a buffer layer made of e.g. silicon oxide or chromium; and
an absorber layer made of e.g. chromium or tantalum nitride.

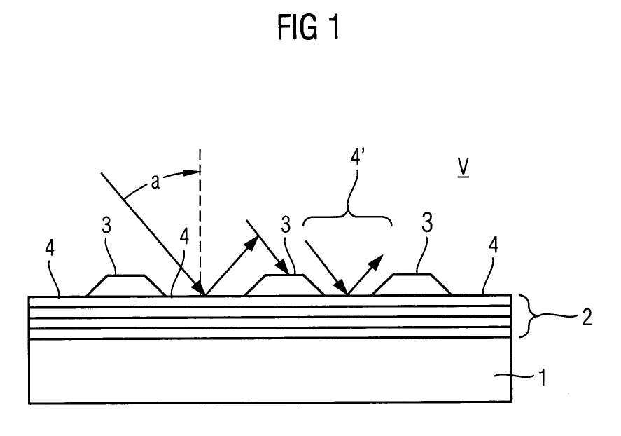

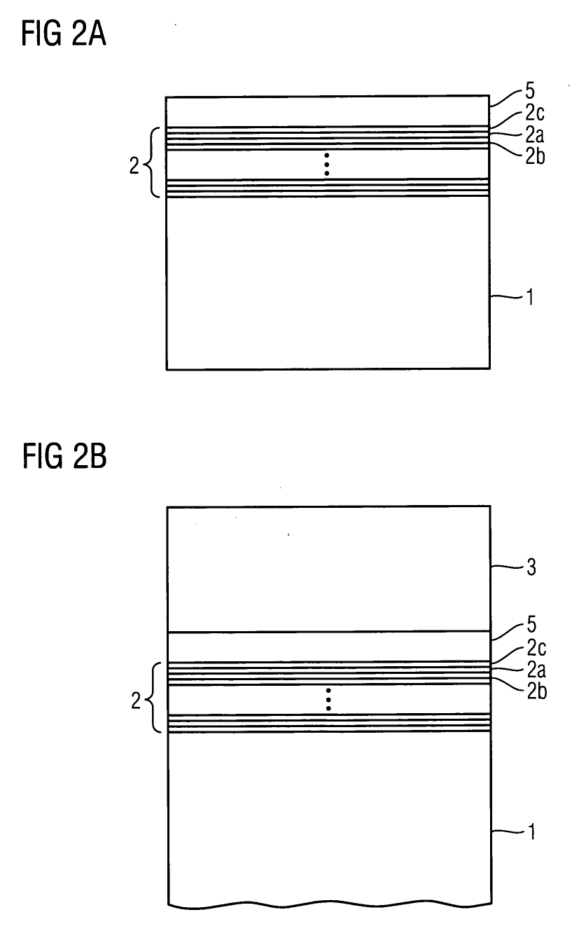

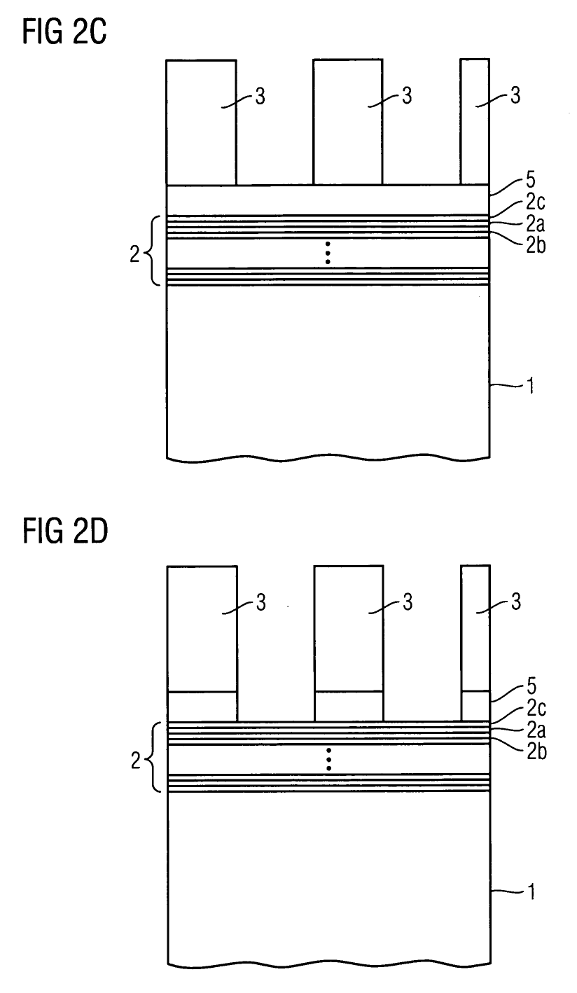

The buffer layer is present particularly in the case of the absorber EUV masks. The elevated sections of this mask type are therefore formed from the absorber layer and the buffer layer. This embodiment corresponds to the mask in accordance with FIG. 1 or 2, so that the Mo/Si multilayer is not patterned. In this embodiment, according to the invention, the capping layer (the last layer of the multilayer) is constructed in conductive fashion or a further layer that is conductive is deposited on the capping layer. If, by way of example, the capping layer comprises silicon, the capping layer can be made conductive by doping with suitable materials.

By contrast, the etched multilayer masks preferably have a conductive base layer and, if appropriate, a smoothing layer, which are arranged between the substrate and the Mo/Si multilayer. The smoothing layer preferably comprises silicon. In the case of this mask type, the elevated sections are formed from the Mo/Si multilayer. In this embodiment, the substrate is itself conductive or has a conductive layer on which the elevated sections are arranged.

In the first embodiment of the invention, the elevated sections of the EUV mask comprise the absorber layer and the buffer layer, while in the second embodiment, the elevated sections are formed from the Mo/Si multilayer.

What is common for both embodiments, however, is that the elevated sections are situated on a conductive surface. The difference between these two embodiments consists, however, in the fact that preferably in the case of the absorber masks the conductive layer has a low light absorption for the EUV radiation, while in the case of the etched multilayer mask the conductive layer is intended to have a high EUV light absorption.

In one particular embodiment of the invention, the substrate comprises ULE® or Zerodur®. The selection of the suitable materials for the substrate is not restricted to ULE® or Zerodur®, so that further materials may also be used. The crucial factor in the selection for the substrate materials is that these materials are intended to have a low coefficient of thermal expansion and little roughness. The typical thickness of the substrate is approximately 6.35 mm.

An electrically conductive layer made of e.g. chromium may be applied on the rear side of the substrate. However, the chromium layer is not necessary for the functioning of the EUV mask. If the chromium layer is present, however, it typically has a thickness of 50 to 100 nm. A multilayer is deposited on the side remote from the chromium layer, the multilayer preferably comprising 60 to 200 thin alternate layers, preferably molybdenum and silicon layers. These layers respectively have a thickness of 2.7 to 2.8 and 4.2 to 4.3 nm. The selection of the materials for the multilayer is not restricted to molybdenum and silicon, so that other materials may also be used. The thickness of the layers is adapted to the wavelength of the incident light and, if a different wavelength is intended to be used, they deviate from the specifications mentioned above.

In one embodiment, the last layer of the multilayer (capping layer) can include silicon if an Mo/Si multilayer is used. The thickness of the capping layer is preferably in the range of 2 to 20 nm, the range of 8 to 12 nm being particularly preferred given the choice of silicon.

A buffer layer made of e.g. SiO2 or chromium may be deposited onto the capping layer. This barrier layer serves as a stop layer during the patterning of the absorber. The selection of the materials for the buffer layer is therefore to be adapted to the etching method used and may accordingly comprise other materials. The thickness of the buffer layer is in the range of preferably 10 to 80 nm.

In one embodiment, the last layer includes a material which absorbs the incident EUV radiation, and may comprise e.g. tantalum nitride or chromium. The thickness of the absorbing layer is preferably in the range of 50 to 100 nm.

The invention therefore provides an EUV mask having elevated sections and trenches lying in between, the mask having at least the following layers:
substrate having a very low coefficient of thermal expansion;
a multilayer made of e.g. molybdenum and silicon;
a capping layer (made of e.g. silicon);
the elevated sections of the EUV mask being arranged on a continuous conductive layer.

Preferably, the EUV mask according to the invention is either an absorber EUV mask or an etched multilayer EUV mask.

In this embodiment, a continuous Cr layer is preferably arranged on one side of the substrate.

In one embodiment, the substrate comprises ULE® or Zerodur®. The thickness of the substrate is approximately 6.35 mm.

In one embodiment, the multilayer according to the invention includes alternate molybdenum and silicon individual layers, the number of the respective individual layers preferably being in the range of 60 to 200.

The thickness of the individual layers is preferably 2.7-2.8 nm for the molybdenum individual layers and 4.3 nm for the silicon individual layers.

The last layer of the multilayer (capping layer) preferably comprises silicon and has a thickness in the range of 2 to 20 nm, preferably 8 to 12 nm.

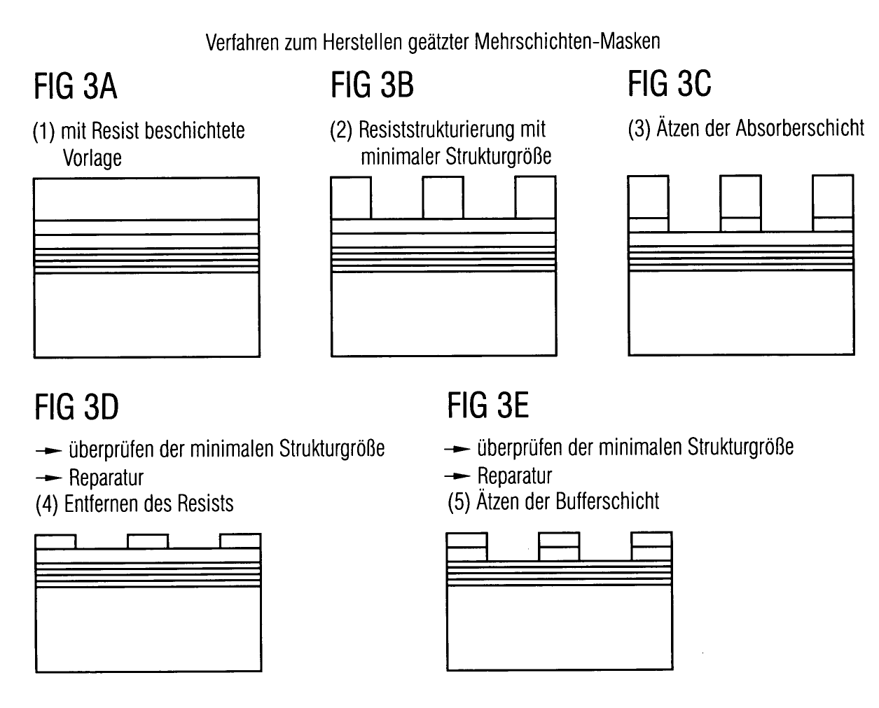

The method for producing an EUV mask of the absorber type according to the invention is explained in more detail with reference to FIGS. 3a-3e.

The absorber layer of the absorber EUV mask preferably comprises tantalum nitride or chromium.

On a layer sequence comprising a substrate, a multilayer, a capping layer, a buffer layer and an absorber layer, a resist is deposited, exposed and patterned (not shown) in order to obtain a structure in accordance with FIG. 3b, in which the absorber layer is partly uncovered. The uncovered sections of the absorber layer are removed in order to obtain a structure in accordance with FIG. 3c. Afterward, firstly the resist (FIG. 3d) and then the uncovered sections of the buffer layer are removed in order to obtain a finished mask (FIG. 3e).

In this embodiment, either the capping layer is conductive or a conductive layer is arranged (not shown) between the capping layer and the elevated sections.

The invention also includes a method for producing EUV masks of the absorber type, having the following processes:
providing a structure having the following layers:
substrate;
multilayer;
capping layer, which is either conductive or has a conductive layer arranged thereon;
buffer layer;
absorber layer;
resist layer;
writing to the resist layer, e.g. by means of electron beams;
subjecting the structure thus obtained to a heat treatment process (post-exposure bake);
developing the resist;
removing the uncovered sections of the absorber layer as far as the buffer layer (e.g. by dry etching), thereby obtaining uncovered sections of the buffer layer;
removing the resist;
examining the structure thus obtained preferably by means of a secondary electron microscope (SEM), and if defects are present, carrying out a repair process;
removing the uncovered sections of the buffer layer through to the capping layer;
examining the structure to be obtained;
repairing the defects possibly present;
final cleaning of the mask.

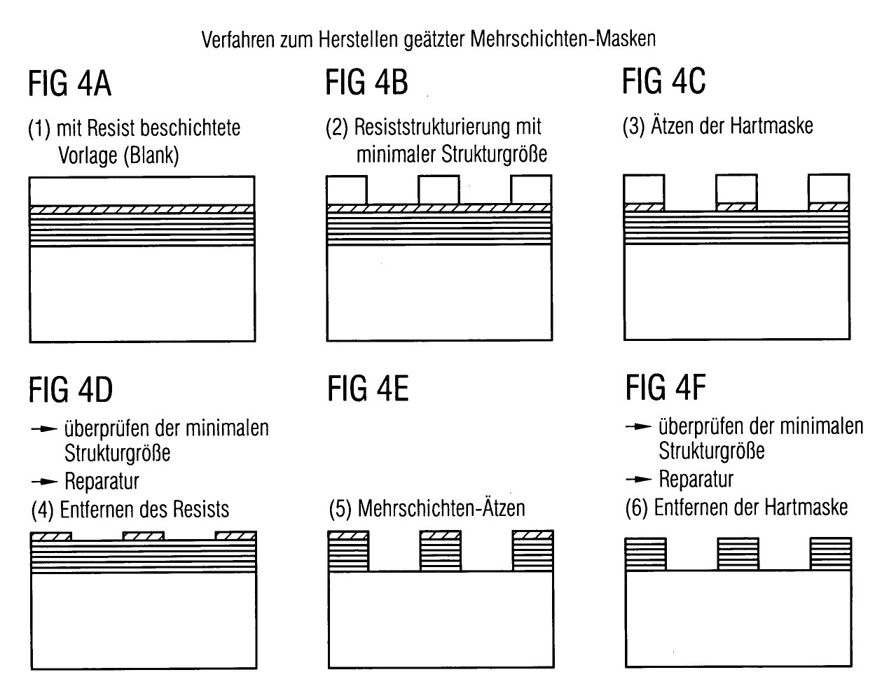

A production method for the EUV etched multilayer masks is illustrated in FIGS. 4a-4f.

On a layer sequence illustrated in FIG. 4a and comprising a substrate, a multilayer with capping layer, a hard mask arranged thereon and a resist deposited thereon, the resist is exposed and patterned in order to attain a structure as illustrated in FIG. 4b. Afterward, the hard mask is etched selectively with respect to the resist, whereby a structure illustrated in FIG. 4c is obtained. After removal of the resist, the hard mask is retained only on specific regions of the multilayer, as illustrated in FIG. 4d, so that the multilayer can then be patterned. The structure that arises after the etching of the multilayer is illustrated in FIG. 4e. In the last process, the hard mask is then removed, whereby a finished etched multilayer mask is obtained (FIG. 4f).

In the embodiment in accordance with FIGS. 4a-4e, there is no separate conductive layer situated below the patterned elevated sections since the entire substrate or at least the region which is in contact with the multilayer is conductive. The conductivity may be achieved by targeted doping of e.g. Zerodur® or ULE® since Zerodur® and ULE® are glasses and ceramics which can easily be doped.

Therefore, the invention also proposes a method for producing EUV masks of the etched multilayer type, having the following processes:
providing a structure having the following layers:
substrate;
if appropriate an electrically conductive layer if the substrate is not itself conductive;
if appropriate a smoothing layer;
multilayer;
hard mask layer;
resist layer;
writing to the resist layer, e.g. by means of electron beams;
subjecting the structure thus obtained to a heat treatment process (post-exposure bake);
developing the resists;
etching the hard mask;
removing the resist;
examining the structure thus obtained preferably by means of a secondary electron microscope (SEM), and if defects are present, carrying out a repair process;
etching the multilayer as far as the substrate if the substrate is conductive, or through to the conductive layer arranged on the substrate;
removing the hard mask;
examining the structure to be obtained preferably by means of a secondary electron microscope (SEM);
repairing the defects possibly present;
final cleaning of the mask.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An EUV mask having elevated sections and trenches lying in between, comprising:
a substrate having a very low coefficient of thermal expansion;
a multilayer;
a capping layer; and
wherein the elevated sections of the EUV mask are arranged on a continuous conductive layer.

2. The EUVmask of claim 1, the multilayer comprising molybdenum and silicon.

3. The EUVmask of claim 1, the capping layer comprising silicon.

4. The EUV mask as claimed in claim 1, wherein the mask is an absorber mask or an etched multilayer mask.

5. The EUV mask as claimed in claim 1, comprising an electrically conductive layer arranged on a rear side of the substrate.

6. The EUV mask of claim 3, where the electrically conductive layer is made of chromium.

7. The EUV mask as claimed in claim 1, wherein the substrate comprises ULE® or Zerodur®.

8. The EUV mask as claimed in claim 1, wherein the substrate has a thickness of 6.35 mm.

9. The EUV mask as claimed in claim 1, wherein the multilayer alternately comprises a first individual layer and a second individual layer.

10. The EUV mask as claimed in claim 9, wherein the number of individual layers in the multilayer is in the range of 60 to 200.

11. The EUV mask as claimed in claim 9, wherein the first individual layer of the multilayer comprises molybdenum and the second individual layer comprises silicon.

12. The EUV mask as claimed in claim 9, wherein the first individual layer of the multilayer has a thickness of 2-3 nm and the second individual layer has a thickness of 4-5 nm if the wavelength of the light used lies between 13 and 14 nm and the angle of incidence lies between 3° and 7°.

13. The EUV mask as claimed in claim 1, wherein the capping layer has a thickness in the range of 2 to 20 nm.

14. The EUV mask as claimed in claim 1, wherein the absorber layer comprises tantalum nitride or chromium.

15. A method for producing EUV masks of an absorber type, comprising:
providing a structure having the following layers: substrate, multilayer, capping layer, which is either conductive or has a conductive layer arranged thereon; buffer layer, absorber layer, and resist layer;
writing to the resist layer;
subjecting a structure thus obtained to a heat treatment process;
developing the resist layer;
removing uncovered sections of the absorber layer as far as the buffer layer, thereby obtaining uncovered sections of the buffer layer;
removing the resist;
examining the structure thus obtained preferably by means of a secondary electron microscope (SEM), and if defects are present, carrying out a repair process;
removing the uncovered sections of the buffer layer through to the capping layer if the capping layer is conductive, or through to the conductive layer arranged on the capping layer;
examining the structure to be obtained;
repairing the defects possibly present; and
final cleaning of the mask.

16. The method as claimed in claim 15, wherein an electrically conductive layer, is arranged on the rear side of the substrate.

17. The method as claimed in claim 15, wherein the substrate comprises ULE® or Zerodur®.

18. The method as claimed in claim 15, wherein the substrate has a thickness of 6.35 mm.

19. The method as claimed in claim 15, wherein the multilayer alternately comprises a first individual layer and a second individual layer.

20. The method as claimed in claim 19, wherein the number of individual layers in the multilayer is in the range of 60 to 200.

21. The method as claimed in claim 19, wherein the first individual layer of the multilayer comprises molybdenum and the second individual layer comprises silicon.

22. The method as claimed in claim 19, wherein the first individual layer of the multilayer has a thickness of 2-3 nm and the second individual layer has a thickness of 4-5 nm if the wavelength of the light used lies between 13 and 14 nm and the angle of incidence lies between 3° and 7°.

23. The method as claimed in claim 19, wherein the capping layer has a thickness in the range of 2 to 20 nm.

24. The method as claimed in claim 19, wherein the absorber layer comprises tantalum nitride or chromium.

25. A method for producing EUV masks of an etched multilayer type, comprising:
providing a structure having the following layers: substrate, if appropriate an electrically conductive layer if the substrate is not itself conductive, if appropriate a smoothing layer, multilayer, hard mask layer, and resist layer;
writing to the resist layer;
subjecting a structure thus obtained to a heat treatment process;
developing the resists;
removing the hard mask;
removing the resist;
examining the structure thus obtained preferably by means of a secondary electron microscope, and if defects are present, carrying out a repair process;
removing the multilayer as far as the substrate if the substrate is conductive, or through to the conductive layer arranged on the substrate;
removing the hard mask;
examining the structure to be obtained preferably by means of a secondary electron microscope;
repairing the defects possibly present; and
final cleaning of the mask.

26. The method as claimed in claim 25, wherein an electrically conductive layer is arranged on the rear side of the substrate.

27. The method as claimed in claim 25, wherein the substrate comprises ULE® or Zerodur®.

28. The method as claimed in claim 25, wherein the substrate has a thickness of 6.35 mm.

29. The method as claimed in claim 25, wherein the multilayer alternately comprises a first individual layer and a second individual layer.

30. The method as claimed in claim 25, wherein the number of individual layers in the multilayer is in the range of 60 to 200.

31. The method as claimed in claim 29, wherein the first individual layer of the multilayer comprises molybdenum and the second individual layer comprises silicon.

32. The method as claimed in claim 29, wherein the first individual layer of the multilayer has a thickness of 2-3 nm and the second individual layer has a thickness of 4-5 nm if the wavelength of the light used lies between 13 and 14 nm and the angle of incidence lies between 3° and 7°.

33. The method as claimed in claim 25, wherein the capping layer has a thickness in the range of 2 to 20 nm.

34. An EUV mask having elevated sections and trenches lying in between, comprising:
a substrate having a very low coefficient of thermal expansion;
a multilayer;
a capping layer; and
means for providing the elevated sections of the EUV mask arranged on a continuous conductive layer.
